(19) United States
(12) Patent Application Publication
(10) Pub. No.: US 2026/0113023 A1
(43) Pub. Date: Apr. 23, 2026

(54) Device and Method of Sampling an Input Signal Employed Thereby

(71) Applicant: Taiwan Semiconductor Manufacturing Company, Ltd., Hsinchu (TW)

(72) Inventors: Tsung-Che Lu, Hsinchu (TW); Chin-Ming Fu, Hsinchu (TW); Chih-Hsien Chang, Hsinchu (TW)

(21) Appl. No.: 19/049,041

(22) Filed: Feb. 10, 2025

Related U.S. Application Data
(60) Provisional application No. 63/708,294, filed on Oct. 17, 2024.

(51) Int. Cl. H03K 5/1534; H03K 5/00

(52) U.S. Cl. CPC H03K 5/1534; H03K 5/00006

(57) ABSTRACT

A device includes a first clock signal generator, a second clock signal generator, an input signal generating circuit, and an input signal sampling circuit. The first clock signal generator generates a first clock signal. The second clock signal generator generates a second clock signal delayed relative to the first clock signal. The input signal generating circuit includes a voltage signal generator and a functional circuit. The voltage signal generator generates a voltage signal. The functional circuit receives the voltage signal and performs one or more circuit functions. The input signal sampling circuit samples values of the voltage signal at rising or falling edges of the second clock signal and to provide the sampled values as an output signal, whereby one or more characteristics of the voltage signal are analyzed based on the output signal.

### CROSS-REFERENCE TO RELATED APPLICATION

The present application claims priority to U.S. Application No. 63/708,294, filed Oct. 17, 2024, the contents of which are incorporated by reference herein in their entirety.

### BACKGROUND

A sampling circuit captures (or samples) values of an input signal at specific points in time, stores (or holds) the sampled values, and provides them collectively as an output signal. The sampled values correspond to the instantaneous levels of the input signal at those points in time. In one example, the sampling circuit receives an input signal and a clock signal, where the input signal is in an analog form and is periodic. Meanwhile, the clock signal transitions between high and low states and has rising and falling edges. The sampling circuit samples the input signal at rising (and/or falling) edges of the clock signal, holds these values, and generates an output signal that includes the sampled values. The output signal can be used for further processing, analysis, or transmission.

### BRIEF DESCRIPTION OF THE DRAWINGS

Aspects of the present disclosure are best understood from the following detailed description when read with the accompanying figures:

FIG. 1 is a schematic block diagram illustrating an exemplary device in accordance with various embodiments of the present disclosure;

FIG. 2 is a schematic timing diagram illustrating an exemplary relationship among signals of a device in accordance with various embodiments of the present disclosure;

FIG. 3 is a schematic block diagram illustrating another exemplary device in accordance with various embodiments of the present disclosure;

FIG. 4 is a schematic block diagram illustrating another exemplary device in accordance with various embodiments of the present disclosure;

FIG. 5 is a schematic circuit/block diagram illustrating an exemplary clock signal generator of a device in accordance with various embodiments of the present disclosure; ;

FIG. 6 is a schematic circuit/block diagram illustrating another exemplary clock signal generator of a device in accordance with various embodiments of the present disclosure;

FIG. 7 is a schematic circuit diagram illustrating another exemplary clock signal generator in accordance with various embodiments of the present disclosure; and

FIG. 8 is a flowchart illustrating an exemplary method of sampling an input signal in accordance with embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Discrete levels of an input signal (such as a periodic analog signal), can be obtained, e.g., to evaluate its quality, by sampling the input signal at specific points in time. The sampled values of the input signal are then held and provided collectively as an output signal. This output signal can subsequently be fed to a signal analyzer, such as an oscilloscope, to identify one or more characteristics of the input signal, e.g., amplitude, frequency, and waveform shape. For example, a sampling circuit receives first and second clock signals, each transitioning between high and low states and having rising and falling edges. The rising (and/or falling) edges of the first clock signal trigger or initiate the sampling of the input signal. The sampling circuit obtains values of an input signal at the rising (and/or falling) edges of the second clock signal. The second clock signal is delayed relative to the first clock signal by at least a predetermined delay (Δt). However, clock signal generators may fail to generate sufficiently small delay (Δt). If the delay (Δt) is too large, the values obtained by the sampling circuit may not be an accurate representation of the input signal.

In certain examples described herein, systems and methods include a device with a clock signal generator that generates the second clock signal by alternating between an original clock signal and its delayed version. This approach may generate a delay (Δt) small enough that the ratio of the period of the second clock signal (e.g., 2.13 ns) to the delay (Δt) (e.g., 23 ps) exceeds 50 (e.g., reaching 92.61). Consequently, the frequency of the output signal is reduced to a lower value (e.g., 5.1 MHz) compared to the higher frequency of the input signal (e.g., 469 MHz). This reduction enables the output signal to accurately represent the input signal, facilitating precise analysis of the input signal.

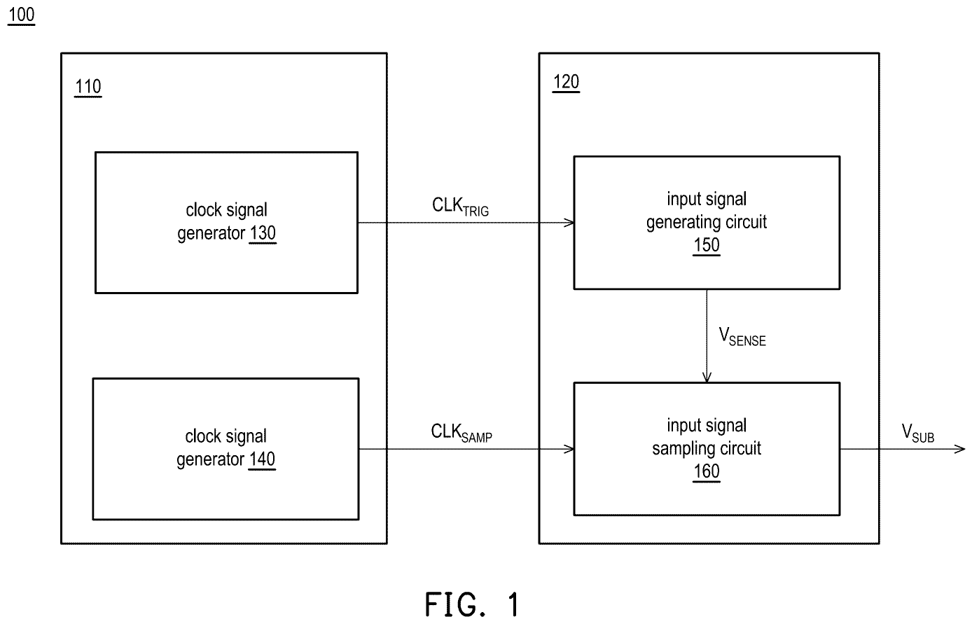

FIG. 1 is a schematic block diagram illustrating an exemplary device 100 in accordance with various embodiments of the present disclosure. The example device 100 uses its own one or more clock signals, e.g., clock signals (CLK_{TRIG}, CLK_{SAMP}), to obtain values of an input signal, e.g., voltage signal (V_{SENSE}), at specific points in time. As illustrated in FIG. 1, the device 100 includes a clock signal generating circuit 110 and an input signal sampler 120. The clock signal generating circuit 110 includes a first clock signal generator 130 that generates a first (or triggering) clock signal (CLK_{TRIG}) and a second clock signal generator 140 that generates a second (or sampling) clock signal (CLK_{SAMP}) having a longer period than the triggering clock signal (CLK_{TRIG}). Each clock signal (CLK_{TRIG}, CLK_{SAMP}) transitions between high and low states and has rising and falling edges.

The input signal sampler 120 obtains values of the voltage signal (V_{SENSE}), as determined by the clock signals (CLK_{TRIG}, CLK_{SAMP}). For example, the input signal sampler 120 includes an input signal generating circuit 150 and an input signal sampling circuit 160. The input signal generating circuit 150 generates an input signal (V_{SENSE}) that is in an analog form and that has a period defined by the rising and falling edges of the triggering clock signal (CLK_{TRIG}). For example, the period of the input signal (V_{SENSE}) starts and ends at the rising (or falling) and falling (or rising) edges of the triggering clock signal (CLK_{TRIG}), respectively. In this exemplary embodiment, the input signal generating circuit 160 performs one or more circuit functions.

The input signal sampling circuit 160 captures (or samples) values of the input signal (V_{SENSE}) at the rising (and/or falling edges) of the sampling clock signal (CLK_{SAMP}), stores (or holds) the sampled values, and provides them collectively as an output signal (V_{SUB}). The sampled values correspond to the instantaneous levels of the input signal (V_{SENSE}) at those points in time. One or more characteristics of the output signal (V_{SUB}) can be analyzed to evaluate the quality of the input signal (V_{SENSE}) using a signal analyzer, such as an oscilloscope, a spectrum analyzer, a voltmeter, any other device capable of measuring a voltage signal, or a combination thereof.

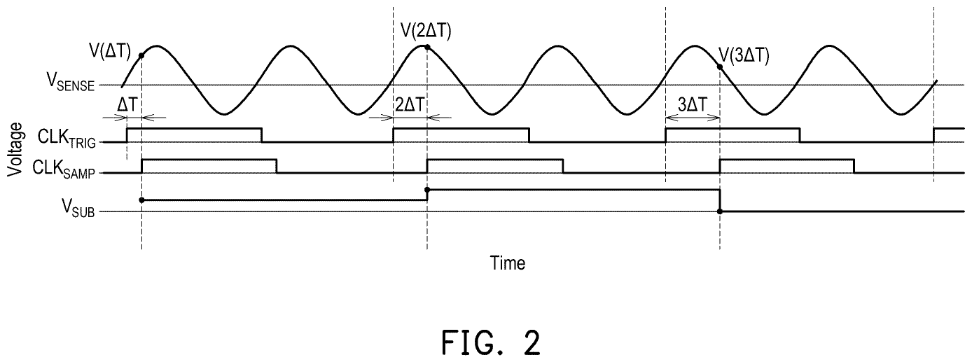

In this exemplary embodiment, the sampling clock signal (CLK_{SAMP}) is delayed by at least a delay (Δt) relative to the triggering clock signal (CLK_{TRIG}). For example, FIG. 2 is a schematic timing diagram illustrating an exemplary relationship among clock signals (CLK_{TRIG}, CLK_{SAMP}) and input signals (V_{SENSE}, V_{SUB}) of a device, e.g., device 100, in accordance with various embodiments of the present disclosure.

As illustrated in FIG. 2, each clock signal (CLK_{TRIG}, CLK_{SAMP}) transitions between high and low states and has rising and falling edges. The input signal (V_{SENSE}) in an analog form and has a period defined by the rising and falling edges of the triggering clock signal (CLK_{TRIG}). For example, the period of the input signal (V_{SENSE}) starts and ends at the rising (or falling) and falling (or rising) edges of the triggering clock signal (CLK_{TRIG}), respectively. That is, the input signal (V_{SENSE}) has a period twice a period of the triggering clock signal (CLK_{TRIG}). In some embodiments, the rising edges of the triggering clock signal (CLK_{TRIG}) trigger or initiate the sampling of the input signal (V_{SENSE}). In such some embodiments, the input signal (V_{SENSE}) is sampled at the rising edges of the sampling clock signal (CLK_{SAMP}). In other embodiments, the rising and/or falling edges of the triggering clock signal (CLK_{TRIG}) trigger or initiate the sampling of the input signal (V_{SENSE}) and the input signal (V_{SENSE}) is sampled at the rising and/or falling edges of the sampling clock signal (CLK_{SAMP}).

In this exemplary embodiments, the sampling clock signal (CLK_{SAMP}) is delayed relative to the triggering clock signal (CLK_{TRIG}) by varying delays, with the delays gradually increasing across multiple periods. For example, the rising edges of the clock signals (CLK_{TRIG}, CLK_{SAMP}) are separated by multiples of a delay (Δt), e.g., Δt, 2Δt, 3Δt, and so on. Similarly, the falling edges of the sampling clock signal (CLK_{SAMP}) are also delayed relative to the falling edges of the triggering clock signal (CLK_{TRIG}) by varying delays. This progressive delay allows the sampling process to spread out the capturing of the values along the input signal (V_{SENSE}), ensuring that no two sampling points are redundant or too closely spaced. As a result, the output signal (V_{SUB}) is reduced to a lower frequency compared to the higher frequency of the voltage signal (V_{SENSE}), without sacrificing the accuracy of the information captured from the input signal (V_{SENSE}).

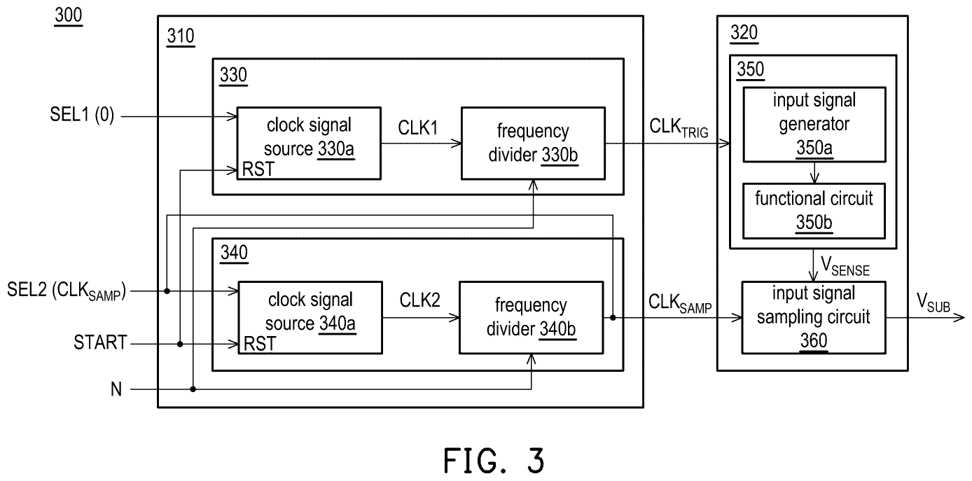

FIG. 3 is a schematic block diagram illustrating another exemplary device in accordance with various embodiments of the present disclosure. As illustrated in FIG. 3, the example device 300, e.g., device 100, includes a clock signal generating circuit 310 and an input signal sampler 320. The clock signal generating circuit 310 includes a first clock signal generator 330 that generates a triggering clock signal (CLK_{TRIG}) and a second clock signal generator 340 that generates a sampling clock signal (CLK_{SAMP}) having a period longer than the triggering clock signal (CLK_{TRIG}). Each clock signal (CLK_{TRIG}, CLK_{SAMP}) transitions between high and low states and has rising and falling edges.

In this exemplary embodiment, the triggering clock signal generator 330 includes a first clock signal source 330a and a first frequency divider 330b. The clock signal source 330a receives an enabling signal (START) at its first input terminal (RST) and a first controlling signal (SEL1) at a second input terminal thereof. The enabling signal (START) enables (e.g., when it is at a high state) the generation of a first higher frequency clock signal (CLK1) at an output terminal of the clock signal source 330a or disables it when it is at a low state. The frequency divider 330b receives the higher frequency clock signal (CLK1) from the clock signal source 330a, divides this higher frequency clock signal (CLK1) by a divisor (N) received at its input terminal, and generates the triggering clock signal (CLK_{TRIG}) at an output terminal thereof.

In certain embodiments, the controlling signal (SEL) is set to a first logic (e.g., low) state and never to a second logic (e.g., high) state that is an inverted version of the first logic state. In such certain embodiments, the triggering clock signal (CLK_{TRIG}) has a period that remains substantially constant over time, in a manner that will be described in detail further below.

The sampling clock signal generator 340 has a similar structure as the triggering clock signal generator 330. For example, the sampling clock signal generator 340 includes a second clock signal source 340a and a second frequency divider 340b. The clock signal source 340a receives the enabling signal (START) at its first input terminal (RST) and a second controlling signal (SEL2) at a second input terminal thereof. The enabling signal (START) enables (e.g., when it is at a high state) the generation of a second higher frequency clock signal (CLK2) at an output terminal of the clock signal source 340a or disables it when it is at a low state. The frequency divider 340b receives the higher frequency clock signal (CLK2) from the clock signal source 340a, divides this higher frequency clock signal (CLK2) by the divisor (N) received at its input terminal, and generates the sampling clock signal (CLK_{SAMP}) at an output terminal thereof.

In certain embodiments, the sampling clock signal (CLK_{SAMP}) serves as the controlling signal (SEL2). In such certain embodiments, the sampling clock signal (CLK_{SAMP}) is delayed relative to the triggering clock signal (CLK_{TRIG}) by multiples of a delay (Δt), in a manner that will be described in detail further below.

The input signal sampler 320 samples a voltage signal (V_{SENSE}), as determined by the clock signals (CLK_{TRIG}, CLK_{SAMP}). For example, the input signal sampler 320 includes an input signal generating circuit 350 and an input signal sampling circuit 360. The input signal generating circuit 350 includes a voltage signal generator 350a and a functional circuit 350b. The voltage signal generator 350a generates an input signal (V_{SENSE}), e.g., a voltage signal, that is in an analog form, that has a period defined by the rising and falling edges of the triggering clock signal (CLK_{TRIG}), and is applied across the functional circuit 350b. In certain embodiments, the voltage signal generator 350a includes a bandgap reference voltage generator, a voltage regulator, a power supply, a digital-to-analog converter (DAC), a voltage-controlled oscillator (VCO), a charge pump, any other circuit that generates a voltage signal, or a combination thereof. In an alternative embodiment, the voltage signal generator 350a is external to the device 300.

The functional circuit 350b receives the voltage signal (V_{SENSE}) and performs one or more circuit functions. In certain embodiments, the functional circuit 350b is a central processing unit (CPU), a memory device, a signal amplifier, an analog-to-digital (ADC) circuit, a logic circuit, other circuit that performs a predetermined circuit function, or a combination thereof. In an alternative embodiment, the functional circuit 350b is external to the device 300.

The input signal sampling circuit 360 captures (or samples) values of the voltage signal (V_{SENSE}) at the rising (and/or falling edges) of the sampling clock signal (CLK_{SAMP}), stores (or holds) the sampled values, and provides them collectively as an output signal (V_{SUB}). The sampled values correspond to the instantaneous voltage levels of the voltage signal (V_{SENSE}) at those points in time. One or more characteristics of the output signal (V_{SUB}) can be analyzed to evaluate the quality of the voltage signal (V_{SENSE}) using a signal analyzer, such as an oscilloscope, a spectrum analyzer, a voltmeter, any other device capable of measuring a voltage signal, or a combination thereof.

From the above description, the sampling clock signal generator 340 has a structure substantially identical to that of the triggering clock signal generator 330. This similarity simplifies the design and fabrication of the device 300.

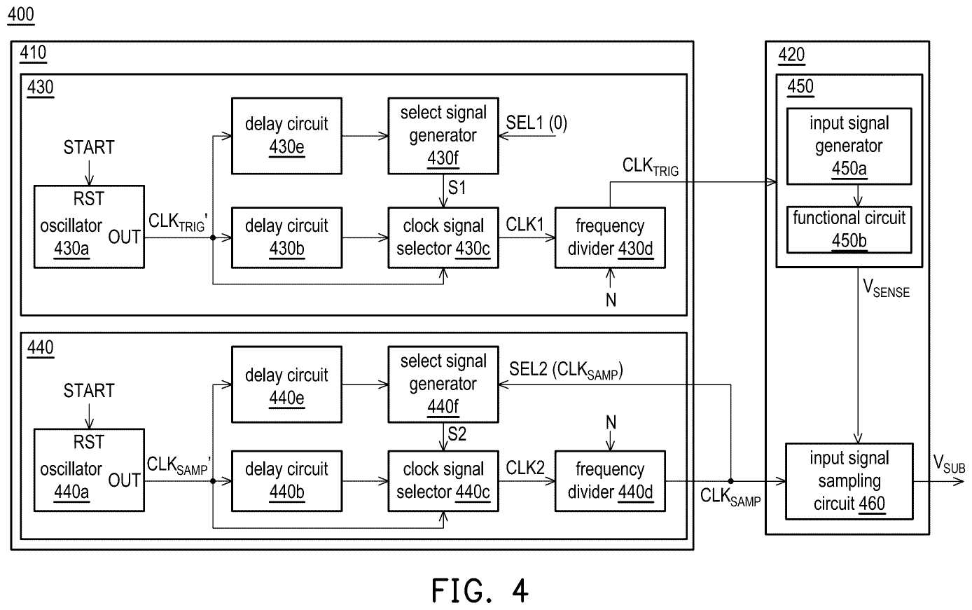

FIG. 4 is a schematic block diagram illustrating another exemplary device in accordance with various embodiments of the present disclosure. As illustrated in FIG. 4, the example device 400, e.g., device 300, includes a clock signal generating circuit 410 and an input signal sampler 420. The clock signal generating circuit 410 includes a first clock signal generator 430 that generates a triggering clock signal (CLK_{TRIG}) and a second clock signal generator 440 that generates a sampling clock signal (CLK_{SAMP}) having a period longer than the triggering clock signal (CLK_{TRIG}). Each clock signal (CLK_{TRIG}, CLK_{SAMP}) transitions between high and low states and has rising and falling edges.

In this exemplary embodiment, the triggering clock signal generator 430 includes an oscillator 430a, a first delay circuit 430b, a clock signal selector 430c, a frequency divider 430d, a second delay circuit 430e, and a select signal generator 430f. The oscillator 430a receives an enabling signal (START) at its input terminal (RST) that enables (e.g., when it is at a high state) the generation of an oscillator signal (CLK_{TRIG}′) at an output terminal (OUT) thereof or disables it when it is at a low state. The delay circuit 430b receives the oscillator signal (CLK_{TRIG}′) from the oscillator 430a, introduces a first delay to the oscillator signal (CLK_{TRIG}′) received thereby, and generates a first delayed version of the oscillator signal (CLK_{TRIG}′) at its output terminal.

The clock signal selector 430d receives the oscillator signal (CLK_{TRIG}′) from the oscillator 430a and the first delayed version of the oscillator signal (CLK_{TRIG}′) from the delay circuit 430b, selects one of the oscillator signal (CLK_{TRIG}′) and the first delayed version of the oscillator signal (CLK_{TRIG}′) in response to a first select signal (S1) received at its input terminal, and provides a higher frequency clock signal (CLK1) at an output terminal thereof that corresponds to the selected one of the oscillator signal (CLK_{TRIG}′) and the first delayed version of the oscillator signal (CLK_{TRIG}′).

The frequency divider 430d receives the higher frequency clock signal (CLK1) from the clock signal selector 430c and divides it by a divisor (N) received at its input terminal, whereby the triggering clock signal generator 430 generates the triggering clock signal (CLK_{TRIG}). The frequency divider 430d provides the triggering clock signal (CLK_{TRIG}) at an output terminal thereof.

The delay circuit 430e receives the oscillator signal (CLK_{TRIG}′) from the oscillator 430a, introduces a second delay to the oscillator signal (CLK_{TRIG}′) received thereby, and generates a second delayed version of the oscillator signal (CLK_{TRIG}′). The select signal generator 430f receives the second delayed version of the oscillator signal (CLK_{TRIG}') from the delay circuit 430e and generates the select signal (S1) in response to a controlling signal (SEL1) at an input terminal thereof, independently of the second delayed version of the oscillator signal (CLK_{TRIG}′) received thereby. In certain embodiments, the controlling signal (SEL1) is set to a first logic (e.g., low) state and never to a second logic (e.g., high) state that is an inverted version of the first logic state. In such certain embodiments, the controlling signal (SEL1) controls the clock signal selector 430c to always select the oscillator signal (CLK_{TRIG}′), never its delayed version. As a result, the triggering clock signal (CLK_{TRIG}) has a period that remains substantially constant over time.

The sampling clock signal generator 440 has a similar structure as the triggering clock signal generator 430. For example, the sampling clock signal generator 440 includes an oscillator 440a, a first delay circuit 440b, a clock signal selector 440c, a frequency divider 440d, a second delay circuit 440e, and a select signal generator 440f. The oscillator 440a receives the enabling signal (START) at its input terminal (RST) that enables (e.g., when it is at a high state) the generation of an oscillator signal (CLK_{SAMP}′) at an output terminal (OUT) thereof or disables it when it is at a low state. The delay circuit 430b receives the oscillator signal (CLK_{SAMP}′) from the oscillator 440a, introduces a first delay to the oscillator signal (CLK_{SAMP}′) received thereby, and generates a first delayed version of the oscillator signal (CLK_{SAMP}′) at its output terminal.

The clock signal selector 440d receives the oscillator signal (CLK_{SAMP}′) from the oscillator 440a and the first delayed version of the oscillator signal (CLK_{SAMP}′) from the delay circuit 440b, selects one of the oscillator signal (CLK_{SAMP}′) and the first delayed version of the oscillator signal (CLK_{SAMP}′) in response to a second select signal (S2) received at its input terminal thereof, and provides a higher frequency clock signal (CLK2) at an output terminal thereof that corresponds to the selected one of the oscillator signal (CLK_{SAMP}′) and the first delayed version of the oscillator signal (CLK_{SAMP}′).

The frequency divider 440d receives the higher frequency clock signal (CLK2) from the clock signal selector 440c and divides it by a divisor (N) received at its input terminal, whereby the sampling clock signal generator 440 generates the sampling clock signal (CLK_{SAMP}). The frequency divider 440d provides the sampling clock signal (CLK_{SAMP}) at an output terminal thereof.

The delay circuit 440e receives the oscillator signal (CLK_{SAMP}′) from the oscillator 440a, introduces a second time delay to the oscillator signal (CLK_{SAMP}′) received thereby, and generates a second delayed version of the oscillator signal (CLK_{SAMP}′). The select signal (S2) generator 440f receives the second delayed version of the oscillator signal (CLK_{SAMP}′) from the delay circuit 440e and generates the select signal (S2) in response to a controlling signal (SEL2) at an input terminal thereof, dependently of the second delayed version of the oscillator signal (CLK_{SAMP}′) received thereby. For example, the sampling clock signal (CLK_{SAMP}′serves as the controlling signal (SEL2). When the second delayed version of the oscillator signal (CLK_{SAMP}′) is at a high state and when the controlling signal (SEL2) transitions from a low state to a high state and back to the low state, the clock signal selector 440d selects the first delayed version of the oscillator signal (CLK_{SAMP}′) as the higher frequency clock signal (CLK2). Otherwise, e.g., when both the second delayed version of the oscillator signal (CLK_{SAMP}′) and the controlling signal (SEL2) are at a low state, the clock signal selector 440d selects the oscillator signal (CLK_{SAMP}′) as the higher frequency clock signal (CLK2).

Because the clock signal selector 440c alternately selects the oscillator signal (CLK_{SAMP}′) and its delayed version as its higher frequency clock signal (CLK2), the sampling clock signal (CLK_{SAMP}) is delayed relative to the triggering clock signal (CLK_{TRIG}) by multiples of a delay (Δt), as described heretofore.

The input signal sampler 420 samples a voltage signal (V_{SENSE}), as determined by the clock signals (CLK_{TRIG}, CLK_{SAMP}). For example, the input signal sampler 420 includes an input signal generating circuit 450 and an input signal sampling circuit 460. The input signal generating circuit 420a includes an input signal generator 450a and a function signal 450b. The input signal generator generates an input signal (V_{SENSE}), e.g., a voltage signal, that is in an analog form and that has a period defined by the rising and falling edges of the triggering clock signal (CLK_{TRIG}). The functional circuit 450b performs one or more circuit functions when the voltage signal (V_{SENSE}) is applied across thereof. In an alternative embodiment, at least one of the voltage signal generator 450a and the functional circuit 450b is external to the device 400.

The input signal sampling circuit 420b captures (or samples) values of the voltage signal (V_{SENSE}) at the rising (and/or falling edges) of the sampling clock signal (CLK_{SAMP}), stores (or holds) the sampled values, and provides them collectively as an output signal (V_{SUB}). The sampled values correspond to the instantaneous voltage levels of the voltage signal (V_{SENSE}) at those points in time. The output signal (V_{SUB}) can be analyzed to evaluate the quality of the voltage signal (V_{SENSE}).

From the above description, the sampling clock signal generator 440 has a structure substantially identical to that of the triggering clock signal generator 430. This similarity simplifies the design and fabrication of the device 400.

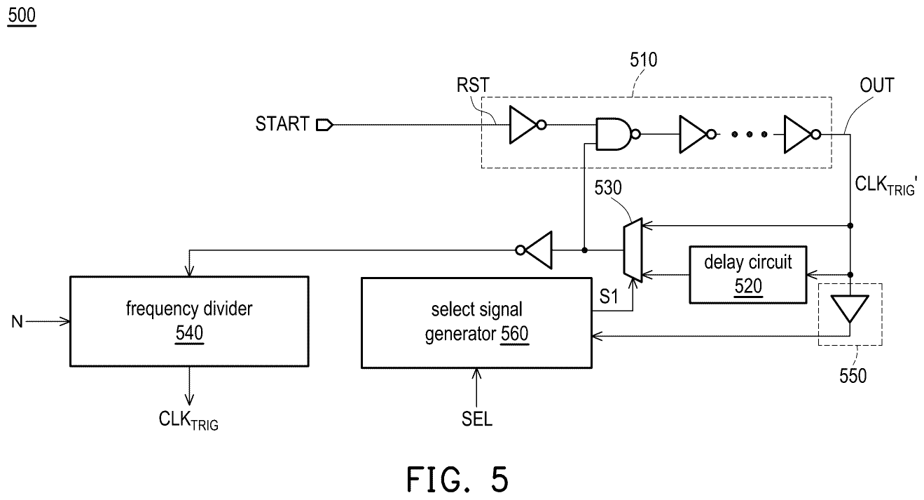

FIG. 5 is a schematic block/circuit diagram illustrating another exemplary clock signal generator in accordance with various embodiments of the present disclosure. As illustrated in FIG. 5, the example clock signal generator 500, e.g., triggering clock signal generator 130, 330, 430, includes an oscillator 510, a first delay circuit 520, a clock signal selector 530, a frequency divider 540, a second delay circuit 550, and a select signal generator 560. The oscillator 510 receives an enabling signal (START) at its input terminal (RST) that enables (e.g., when it is at a high state) the generation of an oscillator signal (CLK_{TRIG}′) at an output terminal (OUT) thereof or disables it when it is at a low state. In this exemplary embodiment, the oscillator 510 includes a ring oscillator implemented with odd number of inverting stages connected in a feedback loop. In an alternative embodiment, the oscillator 510 includes a crystal oscillator, a voltage-controlled oscillator (VCO), a phase-locked loop (PLL), an LC oscillator, any other suitable oscillator, or a combination thereof.

The delay circuit 520 receives the oscillator signal (CLK_{TRIG}′) from the oscillator 510, introduces a first delay to the oscillator signal (CLK_{TRIG}′) received thereby, and generates a first delayed version of the oscillator signal (CLK_{TRIG}′) at its output terminal. In certain embodiments, the delay circuit 520 includes one or more buffer circuits.

The clock signal selector 530 receives the oscillator signal (CLK_{TRIG}′) from the oscillator 510 and the first delayed version of the oscillator signal (CLK_{TRIG}′) from the delay circuit 520, always selects the oscillator signal (CLK_{TRIG}′), i.e., never its delayed version, and provides the oscillator signal (CLK_{TRIG}′) at an output terminal thereof. As such, the triggering clock signal (CLK_{TRIG}) has a period that remains substantially constant over time. In this exemplary embodiment, the clock signal selector 530 includes a multiplexer that has a first input terminal connected to the output terminal of the oscillator 510 and a second input terminal connected to the output terminal of the delay circuit 520. The multiplexer connects the first input terminal thereof to its output terminal in response to a select signal (S1).

The frequency divider 540 receives the oscillator signal (CLK_{TRIG}′) from the clock signal selector 530 and divides the frequency of the oscillator signal (CLK_{TRIG}′) by a divisor (N) received at an input terminal thereof, whereby the triggering clock signal generator 500 generates the triggering clock signal (CLK_{TRIG}). The frequency divider 540 provides the triggering clock signal (CLK_{TRIG}) at its output terminal.

The delay circuit 550 receives the oscillator signal (CLK_{TRIG}′) from the oscillator 510, introduces a second time delay to the oscillator signal (CLK_{TRIG}′) received thereby, and generates a second delayed version of the oscillator signal (CLK_{TRIG}′). In certain embodiments, the delay circuit 550 includes one or more buffer circuits.

The select signal generator 560 receives the second delayed version of the oscillator signal (CLK_{TRIG}′) from the delay circuit 550 and generates the select signal (S1) in response to a controlling signal (SEL) at an input terminal thereof, independently of the second delayed version of the oscillator signal (CLK_{TRIG}′) received thereby. As a result, the triggering clock signal (CLK_{TRIG}) has a period that remains substantially constant over time.

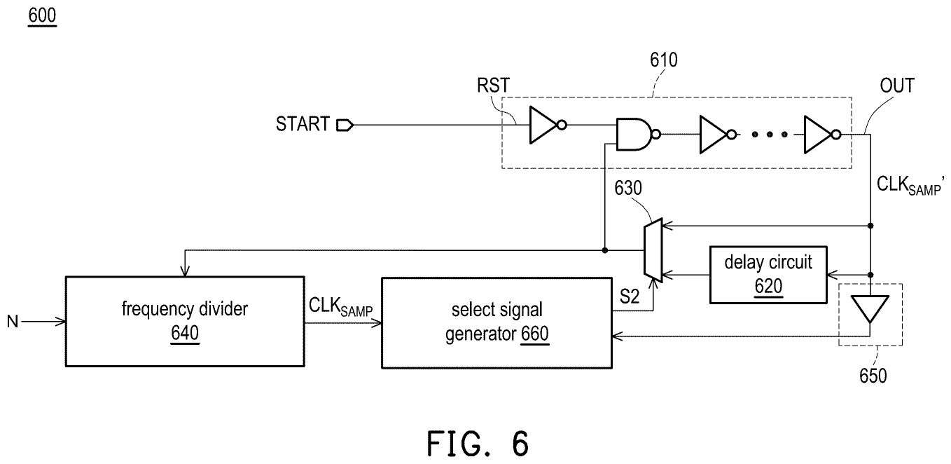

FIG. 6 is a schematic block/circuit diagram illustrating another exemplary clock signal generator in accordance with various embodiments of the present disclosure. As illustrated in FIG. 6, the example clock signal generator 600, e.g., sampling clock signal generator 140, 340, 440, includes an oscillator 610, a first delay circuit 620, a clock signal selector 630, a frequency divider 640, a second delay circuit 650, and a select signal generator 660. The oscillator 610 receives an enabling signal (START) at an input terminal (RST) thereof that enables (e.g., when it is at a high state) the generation of the oscillator signal (CLK_{SAMP}′) at it output terminal (OUT) or disables it when it is at a low state. In this exemplary embodiment, the oscillator 610 includes a ring oscillator implemented with odd number of inverting stages connected in a feedback loop. In an alternative embodiment, the oscillator 610 includes a crystal oscillator, a VCO, a PLL, an LC oscillator, any other suitable oscillator, or a combination thereof.

The delay circuit 620 receives the oscillator signal (CLK_{SAMP}′) from the oscillator 610, introduces a first delay to the oscillator signal (CLK_{SAMP}′) received thereby, and generates a first delayed version of the oscillator signal (CLK_{SAMP}′) at its output terminal. In certain embodiments, the delay circuit 520 includes one or more buffer circuits.

The clock signal selector 630 receives the oscillator signal (CLK_{SAMP}′) from the oscillator 610 and the first delayed version of the oscillator signal (CLK_{SAMP}′) from the delay circuit 620, alternately selects the oscillator signal (CLK_{SAMP}′) and the first delayed version of the oscillator signal (CLK_{SAMP}′), and provides them as an output at an output terminal thereof. In this exemplary embodiment, the clock signal selector 630 includes a multiplexer that has a first input terminal connected to the output terminal of the oscillator 610 and a second input terminal connected to the output terminal of the delay circuit 620. The multiplexer connects the first input terminal or the second input terminals thereof to its output terminal in response to a select signal (S2).

The frequency divider 640 receives output of the clock signal selector 630 and divides (or reduces) its frequency by a divisor (N) received at an input terminal thereof, whereby the sampling clock signal generator 600 generates the sampling clock signal (CLK_{SAMP}). The frequency divider 640 provides the sampling clock signal (CLK_{SAMP}) at its output terminal.

The delay circuit 650 receives the oscillator signal (CLK_{SAMP}′) from the oscillator 610, introduces a second time delay to the oscillator signal (CLK_{SAMP}′) received thereby, and generates a second delayed version of the oscillator signal (CLK_{SAMP}′). In this exemplary embodiment, the delay circuit 650 includes one or more buffer circuits.

The select signal generator 660 receives the second time delay to the oscillator signal (CLK_{SAMP}′) from the delay circuit 650 and generates the select signal (S2) in response to the sampling clock signal (CLK_{SAMP}) at an input terminal thereof. As a result, the sampling clock signal (CLK_{SAMP}) is delayed relative to the triggering clock signal (CLK_{TRIG}) by multiples of a delay (Δt).

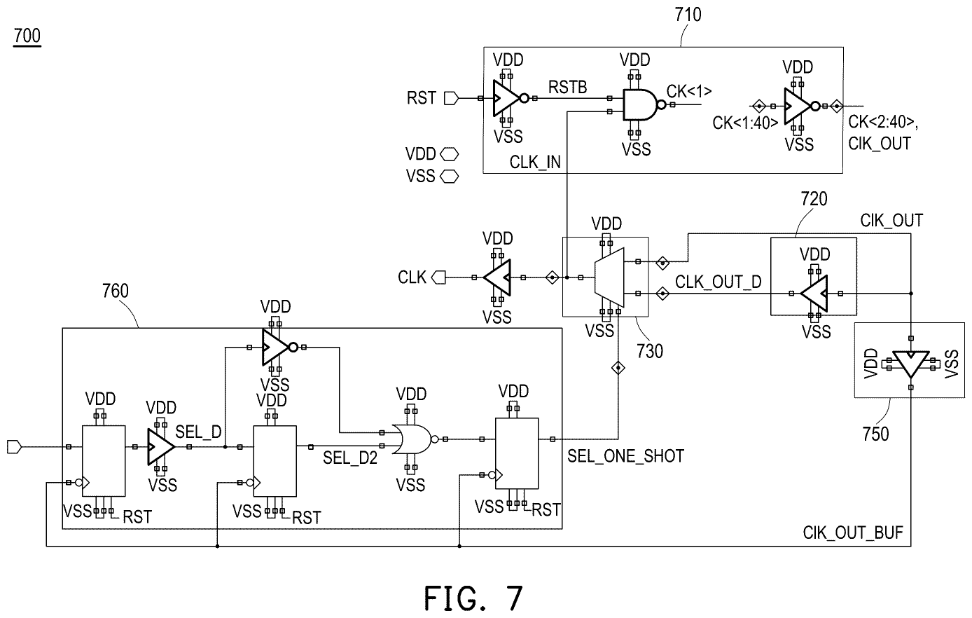

FIG. 7 is a schematic circuit diagram illustrating another exemplary clock signal generator in accordance with various embodiments of the present disclosure. As illustrated in FIG. 7, the example clock signal generator 700, e.g., clock signal generator 130, 140, 330, 340, 430, 440, includes an oscillator 710, a first delay circuit 720, a clock signal selector 730, a second delay circuit 750, and a select signal generator 760. The oscillator 710, e.g., oscillator 510, 610, includes a ring oscillator implemented with odd number of inverting stages connected in a feedback loop. In an alternative embodiment, the oscillator 710 includes a crystal oscillator, a VCO, a PLL, an LC oscillator, any other suitable oscillator, or a combination thereof.

The delay circuit 720, e.g., delay circuit 520, 620, is connected between the oscillator 710 and a first input terminal of the clock signal selector 730, e.g., clock signal selector 530, 630. In this exemplary embodiment, the delay circuit 720 includes one or more buffer circuits. The clock signal selector 730 further has a second input terminal connected to an output terminal of the oscillator 710. In this exemplary embodiment, the clock signal selector 730 includes a multiplexer.

The delay circuit 750, e.g., delay circuit 550, 650, is connected between the output terminal of the oscillator 710 and the select signal generator 760, e.g., select signal generator 560, 660. In this exemplary embodiment, the delay circuit 720 includes one or more buffer circuits. The select signal generator 760 controls operation of the clock signal generator 730. In some embodiments, the select signal generator 760 includes one or more flip-flops and one or more logic gates. Various structures for the select signal generator 760 are contemplated in other embodiments.

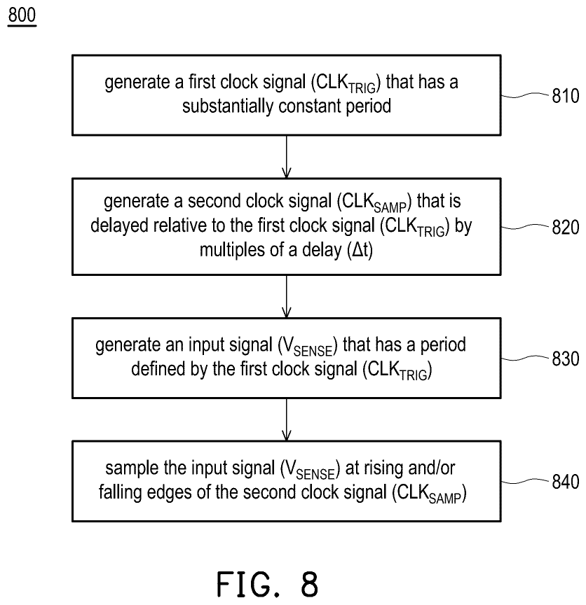

FIG. 8 is a flowchart of an exemplary method 800 of sampling an input signal in accordance with embodiments of the present disclosure. The example method 800 is described with further reference to FIGS. 1-7 for ease of understanding. It is understood that the method 800 is applicable to structures other than those of FIGS. 1-7. Further, it is understood that additional operations can be provided before, during, and after the method 800, and some of the operations described below can be replaced or eliminated, in an alternative embodiment of the method 800.

In operation 810, the device, e.g., device 100, 300-700, generates a first clock signal, e.g., triggering clock signal (CLK_{TRIG}) having a period that remains substantially constant over time.

In operation 820, the device generates a second clock signal, e.g., sampling clock signal (CLK_{SAMP}) that is delayed relative to the triggering clock signal (CLK_{TRIG}) by multiples of a delay (Δt). Each clock signal (CLK_{TRIG}, CLK_{SAMP}) transitions between high and low states and has rising and falling edges.

In operation 830, the device generates an input signal, e.g., voltage signal (V_{SENSE}), that has a period defined by rising and falling edges of the triggering clock signal (CLK_{TRIG}). In operation 840, the device captures (or samples) voltage values of the voltage signal (V_{SENSE}) at the rising (and/or falling edges) of the sampling clock signal (CLK_{SAMP}), stores (or holds) the sampled values, and provides them collectively as an output signal (V_{SUB}).

In an embodiment, a device comprises a first clock signal generator, a second clock signal generator, an input signal generating circuit, and an input signal sampling circuit. The first clock signal generator generates a first clock signal. The second clock signal generator generates a second clock signal delayed relative to the first clock signal. Each clock signal transitions between high and low states and has rising and falling edges. The input signal generating circuit includes a voltage signal generator and a functional circuit. The voltage signal generator generates a voltage signal having a period defined by the rising and falling edges of the first clock signal. The functional circuit receives the voltage signal and performs one or more circuit functions. The input signal sampling circuit samples values of the voltage signal at the rising or falling edges of the second clock signal and to provide the sampled values as an output signal, whereby one or more characteristics of the voltage signal are analyzed based on the output signal.

In another embodiment, a device comprises a first clock signal generator, a second clock signal generator, and an input signal sampling circuit. The first clock signal generator includes a first clock signal selector and a frequency divider. The first clock signal selector receives a first clock signal and a delayed version of the first clock signal and to select the first clock signal as an output and never the first delayed version of the first clock signal. The first frequency divider reduces a frequency of the output and to generate a second clock signal. The second clock signal generator configured to generate a third clock signal. The input signal sampling circuit samples values of a voltage signal using the second and third clock signals and to provide the sampled values as an output signal, whereby one or more characteristics of the voltage signal are analyzed based on the output signal.

In another embodiment, a method of sampling an input signal comprises: generating a first clock signal; dividing a frequency of the first clock signal to generate a second clock signal; generating a third clock signal; introducing a delay to the third clock signal; alternately selecting the third clock signal and the delayed version of the third clock signal to generate an output; reducing a frequency of the output to generate a fourth clock signal; receiving a voltage signal; obtaining values of the voltage signal using the second and fourth clock signals; and providing the values as an output signal, whereby one or more characteristics of the voltage signal are analyzed based on the output signal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
a first clock signal generator configured to generate a first clock signal;
a second clock signal generator configured to generate a second clock signaldelayed relative to the first clock signal, wherein each of the first and second clock signals transitions between high and low states and has rising and falling edges;
an input signal generating circuit including:
a voltage signal generator configured to generate a voltage signal having a period defined by the rising and falling edges of the first clock signal; and
a functional circuit configured to receive the voltage signal and to perform one or more circuit functions; and
an input signal sampling circuit configured to sample values of the voltage signal at the rising or falling edges of the second clock signal and to provide the sampled values as an output signal, whereby one or more characteristics of the voltage signal are analyzed based on the output signal.

2. The device of claim 1, wherein the second clock signal is delayed by multiples of delays relative to the first clock signal.

3. The device of claim 2, wherein:
a first rising of the first clock signal and a first rising edge of the second clock signal are separated by a first delay; and
a second rising edge of the first clock signal and a second rising edge of the second clock signal are separated by a second delay longer than the first delay.

4. The device of claim 2, wherein durations of the delays gradually increase over time.

5. The device of claim 1, wherein the voltage signal has a period twice a period of the first clock signal.

6. The device of claim 1, wherein the first clock signal generator includes:
a clock signal selector configured to receive a third clock signal and a delayed version of the third clock signal and to select the third clock signal as an output but never the delayed version of the third clock signal; and
a frequency divider configured to reduce a frequency of the output and to generate the first clock signal.

7. The device of claim 6, wherein the clock signal selector is configured to select the third clock signal in response to a select signal (S1), wherein the select signal is set to a first logic state and never to a second logic state that is an inverted version of the first logic state.

8. The device of claim 1, wherein the second clock signal generator includes:
a clock signal selector configured to receive a fourth signal and a delayed version of the fourth clock signal, to alternately select between the fourth signal and the delayed version of the fourth clock signal, and to generate an output; and
a frequency divider configured to reduce a frequency of the output and to generate the second clock signal.

9. The device of claim 8, wherein the clock signal selector is configured to alternately select between the fourth signal and the delayed version of the fourth clock signal in response to the second clock signal.

10. A device comprising:
a first clock signal generator including:
a first clock signal selector configured:
to receive a first clock signal and a delayed version of the first clock signal; and
to select the first clock signal as an output and never the first delayed version of the first clock signal; and
a first frequency divider configured to reduce a frequency of the output and to generate a second clock signal; and
a second clock signal generator configured to generate a third clock signal; and
an input signal sampling circuit configured to sample values of a voltage signal using the second and third clock signals and to provide the sampled values as an output signal, whereby one or more characteristics of the voltage signal are analyzed based on the output signal.

11. The device of claim 10, wherein:
the first clock signal selector is further configured to select the first clock signal in response to a select signal; and
the select signal is set to a first logic state and never to a second logic state that is an inverted version of the first logic state.

12. The device of claim 11, wherein the first clock signal generator further includes:
an oscillator configured to generate the first clock signal;
a first delay circuit connected between the oscillator and the first clock signal selector and configured to generate the delayed version of the first clock signal;
a second delay circuit configured to generate a second delayed version of the first clock signal; and
a select signal generator connected between the second delay circuit and the first clock signal selector and configured to generate the select signal independent of the second delayed version of the first clock signal.

13. The device of claim 10, wherein the second clock signal selector is further configured to alternately select a fourth clock signal and a delayed version of the fourth clock signal in response to the third clock signal.

14. The device of claim 13, wherein the second clock signal generator further includes:
an oscillator configured to generate the fourth clock signal;
a first delay circuit connected between the oscillator and the second clock signal selector and configured to generate the delayed version of the fourth clock signal;
a second delay circuit configured to generate a second delayed version of the fourth clock signal; and
a select signal generator connected between the second delay circuit and the second clock signal selector and configured to generate a select signal based on the second delayed version of the fourth clock signal.

15. A method of sampling an input signal, the method comprising:
generating a first clock signal;
dividing a frequency of the first clock signal to generate a second clock signal;
generating a third clock signal;
introducing a delay to the third clock signal;
alternately selecting the third clock signal and the delayed version of the third clock signal to generate an output;
reducing a frequency of the output to generate a fourth clock signal;
receiving a voltage signal;
obtaining values of the voltage signal using the second and fourth clock signals; and
providing the values as an output signal, whereby one or more characteristics of the voltage signal are analyzed based on the output signal.

16. The method of claim 15, further comprising, prior to dividing the frequency of the first clock signal, introducing a delay to the first clock signal and selecting the first clock signal as an output and never the delayed version of the first clock signal.

17. The method of claim 15, further comprising, in response to the fourth clock signal, alternately selecting the third clock signal and the delayed version of the third clock signal.

18. The method of claim 15, further comprising:
prior to dividing the frequency of the first clock signal, introducing a delay to the first clock signal;
selecting the first clock signal as an output in response to a select signal when the select signal at a first logic state; and
setting the select signal at the first logic state and never at the second logic state that is an inverted version of the first logic state.

19. The method of claim 15, further comprising:
generating the voltage signal;
applying the voltage signal across a functional circuit; and
the functional circuit performing one or more circuit functions.

20. The method of claim 15, further comprising introducing a delay to the third clock signal, wherein the ratio of a period of the third clock signal to the delay is equal to or greater than 50.
